(19) United States
(12) Patent Application Publication
(10) Pub. No.: US 2006/0284297 A1
(43) Pub. Date: Dec. 21, 2006

(54) Memory card stack circuit wiring structure

(75) Inventor: Chien-Yuan Chen, Banchiau City (TW)

Correspondence Address: TROXELL LAW OFFICE PLLC, SUITE 1404, 5205 LEESBURG PIKE, FALLS CHURCH, VA, 22041, US

(73) Assignee: Power Digital Card Co., Ltd. & Chien-Yuan Chen

(21) Appl. No.: 11/152,178

(22) Filed: Jun. 15, 2005

(51) Int. Cl. H01L 23/02

(52) U.S. Cl. 257/686

(57) ABSTRACT

A memory card stack circuit wiring structure includes a control chip and a flash memory installed on a substrate in a stack. The layout of circuit wiring is such that the control chip can be connected with the substrate in an L- or U-shape method, in order to simplify the wiring distance of circuit wiring, and to solve the problems of wasting wire material, short-circuit, or breakage of wires caused by an over-length wiring.

### BACKGROUND OF THE INVENTION

(a) Field of the Invention

The present invention relates to a memory card stack circuit wiring structure, and more particularly to a control chip on a flash memory stacked on a substrate, wherein the control chip is connected to the substrate by an L- or U-shape method of circuit wirings to avoid problems of wasting wire material, short-circuit or breakage of wires caused by an over-length wiring.

(b) Description of the Prior Art

To reduce a work consumption and save wire material, while increasing a density and performance of a memory at the same time, has always been a trend of research endeavored by related vendors. A stack memory used by most of the existing vendors includes a dual chip stack memory composed of a flash memory and an SRAM (Static Random Access Memory). Currently, the stack memory constructed by three, four, or five chips is rather popular, as shown in FIG. 1 and FIG. 2.

Referring to FIG. 1 and FIG. 2 at the same time, the conventional comprises primarily a control chip 3, a flash memory 2, and a substrate 1, wherein the flash memory 2 is connected with the substrate 1 by circuit wirings 2a, 2b on two sides of the flash memory 2 respectively, whereas the control chip 3 installed on a top of the flash memory 2 is connected with the substrate 2 by circuit wirings 3a, 3b, 3c, 3d at four edges of the control chip 3 respectively. However, following a highly development of semi-conductor industries, the outlook of elements is on a trend of light-weight, thin, short, and tiny design, whereas the stack technology is toward a development of high pin number and stack function for meeting the requirements of a complex, high density, and ultra-thin memory. Therefore, the wiring method of the current control chip 3 is to fully use a periphery of the control chip 3. Nevertheless, the quantity and distance of wirings, and the defect rate are the problems to be solved by the inventor.

The technique of stack memory is to pursue installing a thinner wafer/chip and a high-level packaging substrate in a thinner package, such that related vendors can expect to further reduce the thickness of wafers in a short period. However, it is used to package a piece of thick and hard silicon glass, and now is to package an ingot of soft and thin silicon. Therefore, the packaging equipment and process of finishing need to be studied again, so as to perform processing to these ultra-thin chips. Another important issue which cannot be overlooked is the packaging substrate, which also needs to be thinner to reduce a packaging thickness, wire track, and space width, so as to perform more complex wiring on different types of substrate.

To satisfy the need of a complex, high density, and ultra-thin memory system, the technique of ultra-thin stack chip and packaging (Intel UT-SCSP) arises. Currently, the most popular packaging substrate is a kind of multi-layer structure. Due to the wiring capability of two or four layers of metal, the cost and availability will be better. Following a highly development of semi-conductor industries, the design of elements has been toward a development for meeting the requirement of high pin number and stack function, whereas the outlook of elements is on a trend of light-weight, thin, short, and tiny design. Therefore, there are also a lot of challenges to the packaging process, such as a more complex design of lead frames, a choice of packaging material, a high density accumulation of number of gold threads in the packaging process, as well as gold thread offsetting and thin package warping generated in mold filling, which are all immediate problems to be solved now by the vendors.

### SUMMARY OF THE INVENTION

The primary object of the present invention is to provide a new type of circuit wirings by which a most effective connection can be obtained between a stack of control chip and memory, and a substrate, in order to solve the current problems of wasting wire material, easiness in generating a short-circuit, or breakage of wires caused by an over-length wiring. Accordingly, the present invention can take cost of circuit wirings into consideration, and largely reduce a problem of defect rate during the process of wiring in the same time, which has completely satisfied the requirements of applying for a patent.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a schematic view of a conventional stack memory.

FIG. 2 shows another schematic view of a conventional stack memory.

FIG. 3 shows a perspective view of an L-shape implementation of the present invention.

FIG. 4 shows a perspective view of a U-shape implementation of the present invention.

FIG. 5 shows a plan view of an L-shape implementation of the present invention.

FIG. 6 shows a plan view of a U-shape implementation of the present invention.

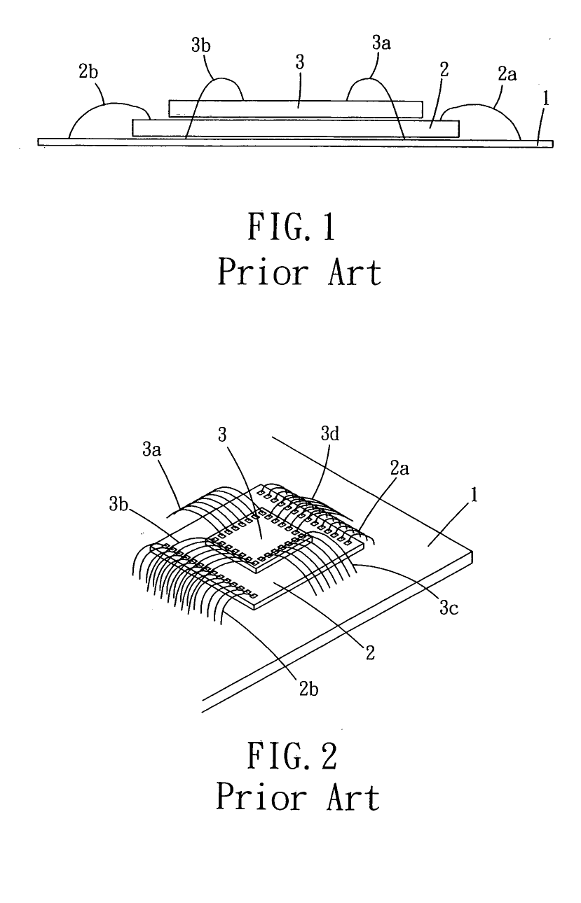

### DETAILED DESCRIPTION OF THE PREFERRED EMBODIMENTS

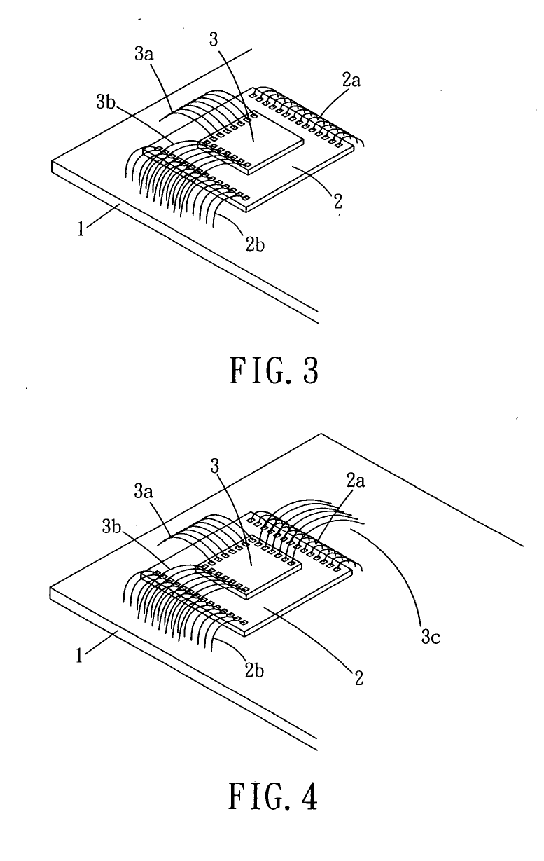

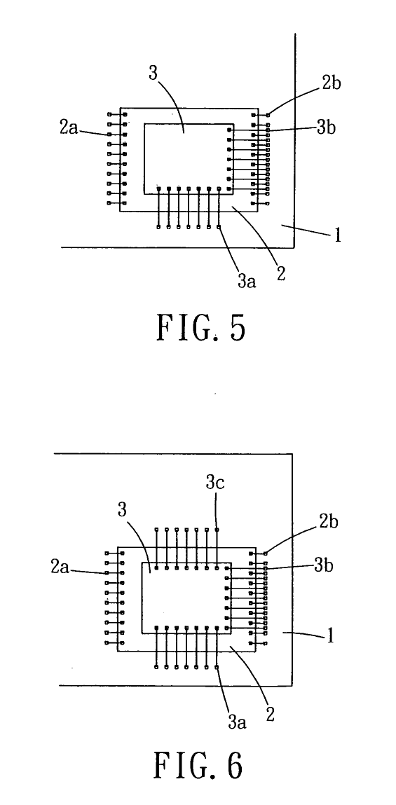

The present invention concentrates on simplifying the wiring distance of the circuit wirings, and solving the problems of wasting wire material, short-circuit, and breakage of wires caused by an over-length wiring. Referring to FIG. 3 and FIG. 4 at the same time, the stacking method also includes a control chip 3, a flash memory 2, and a substrate, wherein the flash memory 2 is connected with the substrate 2 by circuit wirings 2a, 2b at two sides of the flash memory 2 respectively, whereas the control chip 3 is connected with the substrate 1 by circuit wirings 3a, 3b at two sides of the control chip 3, or circuit wirings 3a, 3b, 3c at three sides of the control chip 3, such that the circuit wirings manifest an L-shape or U-shape layout as shown in FIG. 5 and FIG. 6, thereby avoiding a waste of wire material or short-circuit or breakage of wires caused by an over-length wiring.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A memory card stack circuit wiring structure wherein the stacking method includes at least a control chip, a flash memory, and a substrate on which at least more than one chip or flash memory can be installed in a stack; the flash memory being connected with the substrate by circuit wirings at two sides of the flash memory, wherein the control chip stacked on the flash memory at a position closest to an edge of the substrate is the first priority to install circuit wirings for connection with the substrate, thereby simplifying the wiring distance and the connection with other circuits on the substrate.

2. The memory card stack circuit wiring structure according to claim 1, wherein the circuit wiring for the control chip is installed at edges of the control chip in an L-shape for connecting with the substrate.

3. The memory card stack circuit wiring structure according to claim 1, wherein the circuit wiring for the control chip is installed at edges of the control chip in a U-shape for connecting with the substrate.
